(19) United States
(12) Patent Application Publication
(10) Pub. No.: US 2009/0162681 A1
(43) Pub. Date: Jun. 25, 2009

(54) ACTIVATION SOLUTION FOR ELECTROLESS PLATING ON DIELECTRIC LAYERS

(76) Inventor: Artur KOLICS, Dublin, CA (US)

Correspondence Address: LARRY WILLIAMS, 3645 MONTGOMERY DR, SANTA ROSA, CA, 95405-5212, US

(21) Appl. No.: 12/334,460

(22) Filed: Dec. 13, 2008

Related U.S. Application Data
(60) Provisional application No. 61/016,439, filed on Dec. 21, 2007.

(51) Int. Cl. B32B 15/04; B05D 5/12; B01J 31/12

(52) U.S. Cl. 428/469; 427/123; 502/158

(57) ABSTRACT

Presented is a solution to activate an oxide surface for electroless deposition of a metal. The solution comprises a binding agent having at least one functional group capable of forming a chemical bond with the oxide surface and at least one functional group capable of forming a chemical bond with a catalyst. Also present are methods of fabricating electronic devices and electronic devices fabricated using the method.

### CROSS REFERENCES

This application claims benefit of U.S. Patent Application Ser. No. 61/016,439, Docket No. XCR-010, titled “ACTIVATION SOLUTION FOR ELECTROLESS PLATING ON DIELECTRIC LAYERS” to Artur KOLICS, filed Dec. 21, 2007. U.S. Patent Application Ser. No. 61/016,439, filed Dec. 21, 2007, is incorporated herein, in its entirety, by this reference.

### BACKGROUND

This invention pertains to fabrication of electronic devices such as integrated circuits; more specifically, this invention relates to methods and solutions for activation of dielectric oxide surfaces for electroless plating for electronic devices.

Electroless deposition is a process that is frequently used in the fabrication of electronic devices. The process is particularly important for applications requiring deposition of a metal layer onto a dielectric substrate. Electroless deposition processes can readily proceed on certain catalytic surfaces. Usually the catalytic surfaces are metal or metal activated dielectric. Numerous processes have been developed for producing catalytic activity on dielectric surfaces for electroless deposition. In many ways, the known processes provide satisfactory results. However, some of the known processes are complex and may not be practical for manufacturing operations. Another problem is that some known processes are slow and have process times that may be too long for practical manufacturing operations.

### SUMMARY

This invention pertains to electronic devices, more particularly, to metallization of electronic devices that require electroless deposition of metals. The present invention provides one or more unexpected improvements in the solutions used for and methods of fabricating electronic devices such as for fabricating semiconductor devices that use integrated circuits. One or more embodiments of the present invention have been discovered to produce a major reduction in the processing time for activating an oxide surface for electroless deposition. This improvement in processing time can be achieved while maintaining satisfactory properties such as adhesion of the electrolessly deposited metal to the substrate.

One aspect of the present invention is a solution to activate an oxide surface for electroless deposition of a metal layer. According to one embodiment of the present invention, the solution comprises an amount of binding agent. The binding agent has at least one functional group capable of forming a chemical bond with the oxide surface and has at least one functional group capable of forming a chemical bond with a catalyst.

Another aspect of the present invention is a method of fabricating electronic devices. According to one embodiment of the present invention, the method includes providing an oxide surface, exposing the oxide surface to a solution to activate the oxide surface for electroless deposition of metal, and electrolessly depositing a metal layer over the activated oxide surface. The solution to activate the oxide surface comprises an amount of binding agent. The binding agent has at least one functional group capable of forming a chemical bond with the oxide surface and has at least one functional group capable of forming a chemical bond with a catalyst.

A third aspect of the present invention is an electronic device. According to one embodiment of the present invention, the electronic device comprises a dielectric oxide having an oxide surface, a catalyst for electroless deposition, a binder chemically bonded with the dielectric oxide surface and chemically bonded with the catalyst, and a metal layer electrolessly deposited by the catalyst.

It is to be understood that the invention is not limited in its application to the details of construction and to the arrangements of the components set forth in the following description or illustrated in the drawings. The invention is capable of other embodiments and of being practiced and carried out in various ways. In addition, it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods, and systems for carrying out aspects of the present invention. It is important, therefore, that the claims be regarded as including such equivalent constructions insofar as they do not depart from the spirit and scope of the present invention.

### BRIEF DESCRIPTION OF THE DRAWINGS

FIG. 1 is a diagram of an embodiment of the present invention.

Skilled artisans appreciate that elements in the FIGURE are illustrated for simplicity and clarity and have not necessarily been drawn to scale. For example, the dimensions of some of the elements in the FIGURE may be exaggerated relative to other elements to help to improve understanding of embodiments of the present invention

### DESCRIPTION

This invention pertains to electronic devices, more particularly, to metallization of electronic devices. The present invention seeks to overcome one or more problems in fabricating electronic devices such as for fabricating semiconductor devices that use integrated circuits.

Embodiments of and the operation of embodiments of the present invention will be discussed below, primarily in the context of processing semiconductor wafers such as silicon wafers used for fabricating integrated circuits. The following discussion is primarily directed towards silicon electronic devices that use metallization layers having metal layers formed on or in oxide dielectric structures. However, it is to be understood that embodiments in accordance with the present invention may be used for other semiconductor devices, a variety of metal layers, and semiconductor wafers other than silicon.

One aspect of the present invention is a solution to activate an oxide surface for electroless deposition of a metal layer. For the present disclosure, the metal layer is defined as an electrically conductive layer that may be a metal element such as copper, a metal alloy such as cobalt nickel alloy, or a metal composite such as a composite of cobalt tungsten phosphorous. According to one embodiment of the present invention, the solution comprises an amount of binding agent. In general, the binding agent has at least one functional group capable of forming a chemical bond with the oxide surface and has at least one functional group capable of forming a chemical bond with the catalyst. In a preferred embodiment of the present invention, the solution comprises an amount of water-soluble solvent, an amount of catalyst, an amount of binding agent, and an amount of water.

According to preferred embodiments of the present invention, the solution to activate the oxide surface is formulated to activate an oxide surface compatible with silicon integrated circuit technology. Examples of oxides for preferred embodiments of the present invention include but are not limited to silicon dioxide (SiO₂), carbon doped silicon dioxide (SiOC), silicon oxide-based low k dielectrics, and silicon oxides such as SiOCH, SiON, SiOCN, and SiOCHN. Additional preferred oxides for embodiments of the present invention include but are not limited to tantalum pentoxide (Ta₂O₅) and titanium dioxide (TiO₂). For a preferred embodiment of the present invention, the solution is used to activate an oxide that has been patterned for a damascene or dual damascene metallization layer. However, embodiments of the present invention are suitable for use on un-patterned oxides and essentially any type of dielectric oxide typically used in fabricating integrated circuits.

The solution to activate the oxide surface may include a variety of water-soluble solvents. For specific embodiments, the type and amount of water-soluble solvent are selected so that the solution is capable of providing satisfactory solubility for components dissolved in the solvent. In other words, embodiments of the present invention use an effective amount of water-soluble solvent. As an option, a single water-soluble solvent may be used or a mixture of dissimilar water-soluble solvents may be used. A list of suitable water-soluble solvents for some embodiments of the present invention includes, but is not limited to, dimethylsulfoxide, formamide, acetonitrile, alcohol, or mixtures thereof. Other water-soluble solvents suitable for embodiments of the present invention will be clear to persons of ordinary skill in the art, in view of the present disclosure.

There are numerous catalysts suitable for carrying out electroless deposition. Preferred embodiments of the present invention use compounds of catalysts known to be suitable for electroless deposition and catalytic sources dissolved in the solution. Preferred embodiments of the solution to activate the oxide surface for electroless deposition of the metal includes catalytic sources such as a palladium compound, a platinum compound, a ruthenium compound, a copper compound, a silver compound, a rhenium compound, or mixtures thereof. For specific embodiments, the type and amount of water-soluble solvent are selected so that the solution is capable of providing an effective amount of catalyst to the oxide surface to accomplish electroless deposition.

The binding agents for embodiments of the present invention can have numerous chemical compositions. There are many choices for the at least one functional group capable of forming a chemical bond with the oxide surface and for the at least one functional group capable of forming a chemical bond with the catalyst. Some embodiments of the present invention may include binding agents having two or three or more functional groups capable of forming a chemical bond with the oxide surface. Similarly, some embodiments of the present invention may include binding agents having two or three or more functional groups capable of forming a chemical bond with the catalyst. Optionally, binding agents may be selected that include different types of functional groups capable of forming chemical bonds with the oxide surface. Binding agents may be selected that include different types of functional groups capable of forming chemical bonds with the catalyst. Embodiments of the present invention may also use mixtures of different types of binding agents.

According to a preferred embodiment of the present invention, the binding agent includes an alkoxysilane such as a mono-alkoxy silane and such as a di-alkoxy silane for forming the chemical bond with the oxide surface. The binding agent further includes one or more polar groups such as, but not limited to, an amine group, an imine group, a carboxylate group, a phosphate group, a phosphonate group, and an epoxy group forming the chemical bond with the catalyst. As an option, binding agents according to some embodiments of the present invention may include dissimilar polar groups or mixtures of dissimilar polar groups. For specific embodiments of the present invention, the type and amount of binding agent are selected so that the solution is capable of binding an effective amount of catalyst to the oxide surface to accomplish electroless deposition.

Preferably, the water used for the solution is high purity deionized water such as that typically used for manufacturing semiconductor devices. The addition of water to the solution can provide one or more effects. In some instances, the presence of the water can aid in dissolving one or more of the components added to the solution. For some embodiments of the present invention, water may be involved in one or more chemical reactions involving the binding agent and the oxide surface. Generally, the amount of water added to the solution is selected so as to make the solution effective for activating the oxide surface. For some embodiments of the present invention, the amount of water makes up less than about 20% of the total volume of the solution. For other embodiments of the present invention, the amount of water makes up less than about 10% of the total volume of the solution.

According to one embodiment of the present invention, the solution to activate the oxide surface includes catalyst compound from about 0.01 gram/liter to about 1 gram/liter, water-soluble solvent from about 70 weight percent to 95 weight percent, binding agent from about 0.5 weight percent to about 10 weight percent, and water from about 1 weight percent to about 20 weight percent.

In a more specific embodiment of the present invention, the solution to activate the oxide surface includes catalyst compound comprising a palladium compound from about 0.01 gram/liter to about 1 gram/liter, water-soluble solvent comprising dimethylsulfoxide from about 70 weight percent to 95 weight percent, binding agent comprising an alkoxyalkylamine silane from about 0.5 weight percent to about 10 weight percent, and water from about 1 weight percent to about 20weight percent.

For another embodiment of the present invention, the solution includes a binding agent having the general formula (R₁—O)₄₋ₙMXₙ where M is silicon, germanium, or tin; X is the functional group capable of forming the chemical bond with the catalyst; R₁—O is the functional group capable of forming the chemical bond with the oxide surface, O is oxygen; and n is 1, 2, or 3. A preferred embodiment of the present invention has X comprising one or more polar groups such as, but not limited to, amine, imine, epoxy, hydroxyl, carboxy, carboxylate, phosphate, phosphonate, sulfonate, boronate, carbonate, bicarbonate, or combinations thereof. Preferably, R₁ is an organic group such as an alkyl group and R₁—O is an alkoxy group such as methoxy, ethoxy, and propoxy. For a more preferred embodiment of the present invention, (R₁—O)₄₋ₙ includes one or more groups such as, but not limited to, methoxy, ethoxy, propoxy, and combinations thereof and Xₙ comprises one or more groups such as, but not limited to, amine, imine, epoxy, hydroxyl, carboxy, carboxylate, phosphate, phosphonate, and combinations thereof. In another preferred embodiment, R₁ is an alkyl group, M is silicon, and X is an alkylamine.

Another aspect of the present invention is a method of fabricating electronic devices. According to one embodiment of the present invention, the method includes providing an oxide surface, exposing the oxide surface to a solution to activate the oxide surface for electroless deposition of metal, and electrolessly depositing a metal layer onto the activated oxide surface. The solution to activate the oxide surface is essentially the same composition and has essentially the same properties described for the solution presented supra. In general, the solution to activate the oxide surface comprises an amount of binding agent substantially as presented supra. The binding agent has at least one functional group, substantially as presented supra, capable of forming a chemical bond with the oxide surface and has at least one functional group, substantially as presented supra, capable of forming a chemical bond with the catalyst. In a preferred embodiment, the solution to activate the oxide surface comprises an amount of water-soluble solvent substantially as presented supra, an amount of catalyst substantially as presented supra, an amount of binding agent substantially as presented supra, and an amount of water substantially as presented supra.

Additional embodiments of the present invention include the method of fabricating electronic devices wherein the solution to activate the oxide surface includes dissimilar compositions of the solution such as having each of the compositions presented supra used in a different embodiment of the method. Since detailed descriptions of compositions are presented supra, they will not be repeated here for the description of method embodiments of the present invention.

In preferred embodiments of the method of fabricating electronic devices, electrolessly depositing the metal layer over the activated oxide surface is accomplished by placing the activated oxide surface into an electroless plating solution. The electroless plating solution is formulated so as to form a metal, metal alloy, or metal composite film. Examples of suitable metal films for embodiments of the present invention include, but are not limited to, copper, cobalt, nickel, cobalt tungsten, cobalt tungsten phosphorus. Descriptions of electroless deposition processes suitable for embodiments of the present invention can be found in U.S. Pat. No. 6,794,288 to Kolics et al. and U.S. Pat. No. 6,911,076 to Kolics et al.; the contents of all of these patents are incorporated herein, in their entirety by this reference. If needed, the method may also include rinsing the activated oxide surface using a liquid that is substantially free of species such as ions and such as complexing agents. For some embodiments of the present invention, the rinse may be accomplished using a high purity deionized water rinse.

According to the present invention, another embodiment of the method of fabricating electronic devices further comprises rinsing the activated oxide surface with a solution comprising a reducing agent prior to electrolessly depositing the metal layer. Preferably, the rinsing of the activated oxide surface with the solution comprising the reducing agent is performed for up to about 60 seconds at a temperature of about 10° C. to about 95° C. For some embodiments of the present invention, the solution comprising the reducing agent further comprises an amount of pH adjustor, an amount of complexing agent, an amount of surfactant, or combinations thereof. A list of suitable reducing agents for embodiments of the present invention include, but are not limited to, borane, borohydride, hydrazine, hypophosphite, aldehyde, ascorbate and mixtures thereof.

In another embodiment of the present invention, providing the oxide surface includes providing an oxide such as, but not limited to, SiO₂, SiOC, SiOCH, SiON, SiOCN, SiOCHN, Ta₂O₅, and TiO₂, and the oxide surface is immersed in the solution to activate the oxide surface for a time from about 30 seconds to about 600 seconds at a temperature from about 10° C. to about 95° C. According to a more preferred embodiment, the oxide surface is immersed in the solution to activate the oxide surface from about 60 seconds to about 180 seconds at a temperature from about 50° C. to about 70° C.

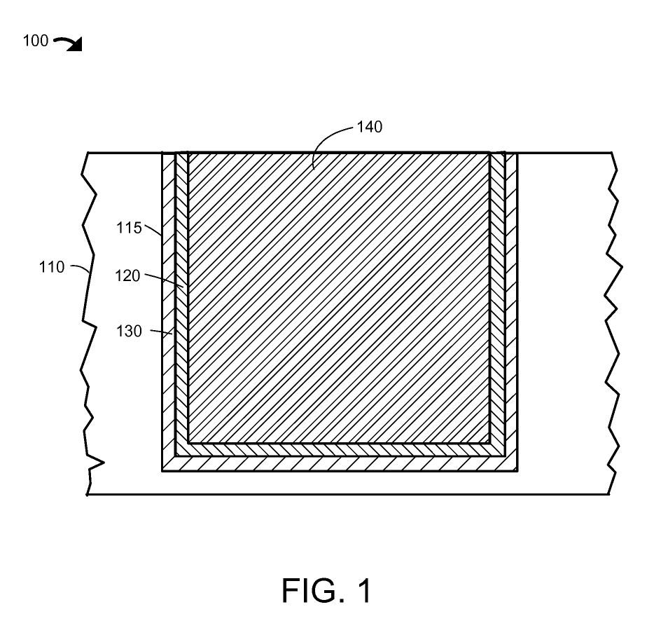

A third aspect of the present invention is an electronic device. Reference is now made to FIG. 1 where there is shown a diagram of a cross-sectional side view of a portion of electronic device 100 according to one embodiment of the present invention. Electronic device 100 comprises a dielectric oxide 110 having an oxide surface 115, a catalyst 120 for electroless deposition, a binder 130 chemically bonded with oxide surface 115 and chemically bonded with catalyst 120, and a metal layer 140 electrolessly deposited on catalyst 120.

It should be noted that the diagram in FIG. 1 is not drawn to scale. More specifically, the thickness of catalyst 120 and the thickness of binder 130 are exaggerated for illustration. Furthermore, the diagram in FIG. 1 shows electronic device 100 having metal layer 140 as a gapfill metal. It is to be understood that this is an option for some embodiments of the present invention; other embodiments may include having metal layer 140 provided as a non-filling layer and further processing includes complete gapfill. Still further, the diagram shown in FIG. 1 presents a planarized surface so as to form a damascene metallization structure.

Preferably, binder 130 comprises a chemical reaction product from a reaction of oxide surface 115 and a reaction of catalyst 120 with a binding agent. The binding agent has the general formula (R₁—O)₄₋ₙMXₙ where M is silicon, germanium, or tin; X is a functional group capable of forming the chemical bond with catalyst 120; R₁—O is a functional group capable of forming the chemical bond with oxide surface 115, O is oxygen; and n is 1, 2, or 3. Preferably, dielectric oxide 110 comprises an oxide such as, but not limited to one of SiO₂, SiOC, SiOCH, SiON, SiOCN, SiOCHN, Ta₂O₅, and TiO₂. Catalyst 120 includes one or more metals such as, but not limited to, palladium, platinum, ruthenium, copper, silver, rhenium, and mixtures thereof.

For some embodiments of the present invention, metal layer 140 includes one or more elements such as, but not limited to, copper, cobalt, nickel, tungsten, phosphorus, and mixtures thereof. For applications such as copper metallization, metal layer 140 is preferably copper or a diffusion barrier for copper if a diffusion barrier is needed.

For some embodiments of the present invention, binder 130 has a general chemical formula O₄₋ₙMXₙ where O, M, X, and n are defined as supra. According to a preferred embodiment, binder 130 comprises O₄₋ₙMXₙ and X comprises amine, imine, epoxy, hydroxyl, carboxy, carboxylate, phosphate, phosphonate, or combinations thereof. In another preferred embodiment, the binding agent used for obtaining binder 130 includes R₁ as an alkyl group. Also for preferred embodiments of the present invention, M is silicon.

Embodiments of the present invention may include binder 130 as a polymer network. The polymer network can be accomplished by using binding agents that are capable of forming lateral bonds with adjacent binding agents that have chemically attached to the oxide surface. As a possibility, a binding agent such as an alkoxy-alklyamine silane with three alkoxy groups can bond with oxide surface 115 and form a polymer network of silicon oxygen bonds.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of the present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

As used herein, the terms “comprises,” “comprising,” “includes,” “including,” “has,” “having,” “at least one of,” or any other variation thereof, are intended to cover a non-exclusive inclusion. For example, a process, method, article, or apparatus that comprises a list of elements is not necessarily limited only to those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

What is claimed is:

1. A solution to activate an oxide surface for electroless deposition, the solution comprising:
an amount of water-soluble solvent;
an amount of catalyst;
an amount of binding agent having at least one functional group capable of forming a chemical bond with the oxide surface and having at least one functional group capable of forming a chemical bond with the catalyst; and
an amount of water.

2. The solution of claim 1, wherein the water-soluble solvent is dimethylsulfoxide, formamide, acetonitrile, alcohol, or mixtures thereof.

3. The solution claim 1, wherein a source for the catalyst is a palladium compound, a platinum compound, a ruthenium compound, a copper compound, a silver compound, a rhenium compound, or mixtures thereof.

4. The solution claim 1, wherein the binding agent comprises mono-alkoxy silane or di-alkoxy silane and at least one member from the group consisting of an amine group, an imine group, a carboxylate group, a phosphate group, a phosphonate group, and an epoxy group.

5. The solution claim 1, wherein the oxide comprises at least one of SiO₂, SiOC, SiOCH, SiON, SiOCN, SiOCHN, Ta₂O₅, and TiO₂.

6. The solution of claim 1, wherein the catalyst is added to the solution as a compound in an amount from about 0.01 grams per liter to 1 grams per liter, the amount of water-soluble solvent is 70 weight percent to 95 weight percent the amount of binding agent is 0.5 weight percent to 10 weight percent, and the amount of water is 1 weight percent to 20 weight percent.

7. The solution of claim 1, wherein a source for the catalyst is a palladium compound and the amount is 0.01 grams per liter to 1 grams per liter, the water-soluble solvent is dimethylsulfoxide and the amount is 70 weight percent to 95 weight percent, the binding agent is an alkoxyalkylamine silane and the amount is about 0.5 weight percent to about 10 weight percent, and the amount of water is about 1 weight percent to about 20 weight percent.

8. The solution of claim 1, wherein the binding agent has the general formula (R₁—O)₄₋ₙMXₙ where
M is silicon, germanium, or tin;
X is the functional group capable of forming the chemical bond with the catalyst;
R₁—O is the functional group capable of forming the chemical bond with the oxide surface, O is oxygen; and
n is 1, 2, or 3.

9. The solution of claim 8, wherein Xₙ comprises amine, imine, epoxy, hydroxyl, carboxy, carboxylate, phosphate, phosphonate, or combinations thereof.

10. The solution of claim 8, wherein Xₙ comprises, sulfonate, boronate, carbonate, bicarbonate, or combinations thereof.

11. The solution of claim 8, wherein R₁ is an alkyl group.

12. The solution of claim 8, wherein (R₁—O)₄₋ₙ comprises methoxy, ethoxy, propoxy, or combinations thereof.

13. The solution of claim 8, wherein (R₁—O)₄₋ₙ comprises methoxy, ethoxy, propoxy, or combinations thereof and X comprises amine, imine, epoxy, hydroxyl, carboxy, carboxylate, phosphate, phosphonate, or combinations thereof.

14. The solution of claim 8, wherein R₁ is an alkyl group, M is silicon, and X is an alkylamine.

15. The solution of claim 1, wherein the amount of water is less than about 10% of the total volume.

16. A method of fabricating an electronic device, the method comprising:
providing an oxide surface;
exposing the oxide surface to a solution to activate the oxide surface for electroless deposition of metal, the solution to activate the oxide surface comprising
an amount of water soluble solvent,
an amount of catalyst;
an amount of binding agent having at least one functional group capable of forming a chemical bond with the oxide surface and having at least one functional group capable of forming a chemical bond with the catalyst; and
an amount of water; and
electrolessly depositing a metal layer over the activated oxide surface.

17. The method of claim 16, wherein the water-soluble solvent is dimethylsulfoxide, formamide, acetonitrile, alcohol, or mixtures thereof.

18. The method claim 16, wherein the binding agent comprises mono-alkoxy silane or di-alkoxy silane and at least one from the group consisting of an amine group, an imine group, a carboxylate group, a phosphate group, a phosphonate group, and an epoxy group.

19. The method of claim 16, wherein the binding agent has the general formula (R₁—O)₄₋ₙMXₙ where
M is silicon, germanium, or tin;
X is the functional group capable of forming the chemical bond with the catalyst;
R₁—O is the functional group capable of forming the chemical bond with the oxide surface, O is oxygen; and
n is 1, 2, or 3.

20. The method of claim 19, wherein R₁ is an alkyl group, M is silicon, and X is an alkylamine.

21. The method of claim 16, wherein electrolessly depositing the metal layer over the activated oxide surface comprises placing the activated oxide surface into an electroless plating bath so as to form a metal, metal alloy, or metal composite.

22. The method of claim 16, further comprising rinsing the activated oxide surface with a solution comprising a reducing agent prior to electrolessly depositing the metal layer.

23. The method of claim 16, further comprising rinsing the activated oxide surface, prior to electrolessly depositing the metal layer, with a reducing solution for up to about 60 seconds at a temperature of about 10° C. to about 95° C., the reducing solution comprising an amount of reducing agent and further comprising an amount of pH adjustor, an amount of complexing agent, an amount of surfactant, or combinations thereof.

24. The method of claim 16, wherein the oxide surface comprises at least one selected from the group consisting of SiO₂, SiOC, SiOCH, SiON, SiOCN, SiOCHN, Ta₂O₅, and TiO₂, and the oxide surface is immersed in the solution to activate the oxide surface from about 30 seconds to about 600 seconds at a temperature from about 10° C. to about 95° C.

25. The method of claim 16, wherein the oxide surface is immersed in the solution to activate the oxide surface from about 30 seconds to about 600 seconds at a temperature from about 10° C. to about 95° C.

26. The method of claim 16, wherein the oxide surface is immersed in the solution to activate the oxide surface from about 60 seconds to about 180 seconds at a temperature from about 50° C. to about 70° C.

27. The method of claim 16, further comprising rinsing the activated oxide surface with a solution comprising a reducing agent prior to electrolessly depositing the metal layer, the reducing agent comprising borane, borohydride, hydrazine, hypophosphite, aldehyde, ascorbate, or mixtures thereof.

28. An electronic device comprising,
a dielectric oxide having an oxide surface,
a catalyst for electroless deposition,
a binder chemically bonded with the dielectric oxide surface and chemically bonded with the catalyst, and
a metal layer electrolessly deposited on the catalyst.

29. The electronic device of claim 28, wherein the binder comprises a chemical reaction product from a reaction of the oxide surface and a reaction of the catalyst with a binding agent having the general formula (R₁—O)₄₋ₙMXₙ where
M is silicon, germanium, or tin;
X is a functional group capable of forming the chemical bond with the catalyst;
R₁—O is a functional group capable of forming the chemical bond with the oxide surface, O is oxygen; and
n is 1, 2, or 3.

30. The electronic device of claim 29, wherein the oxide comprises at least one of SiO₂, SiOC, SiOCH, SiON, SiOCN, SiOCHN, Ta₂O₅, and TiO2.

31. The electronic device of claim 29, wherein the catalyst is palladium, platinum, ruthenium, copper, silver, rhenium, or mixtures thereof.

32. The electronic device of claim 29, wherein the metal layer comprises at least one of copper, cobalt, nickel, tungsten, phosphorus, and mixtures thereof.

33. The electronic device of claim 29, wherein the binder comprises O₄₋ₙMXₙ.

34. The electronic device of claim 29, wherein the binder comprises O₄₋ₙMXₙ and X comprises amine, imine, epoxy, hydroxyl, carboxy, carboxylate, phosphate, phosphonate, or combinations thereof.

35. The electronic device of claim 29, wherein R₁ is an alkyl group.

36. The electronic device of claim 29, wherein the binder comprises a polymer network.

37. A method of fabricating an electronic device, the method comprising:
providing an oxide surface;
exposing the oxide surface to a solution to activate the oxide surface for electroless deposition of metal, the solution to activate the oxide surface comprising an amount of binding agent having at least one functional group capable of forming a chemical bond with the oxide surface and having at least one functional group capable of forming a chemical bond with a catalyst; and
electrolessly depositing a metal layer over the activated oxide surface.
